(19) United States
(12) Patent Application Publication
(10) Pub. No.: US 2023/0356350 A1
(43) Pub. Date: Nov. 9, 2023

(54) POLISHING APPARATUS AND METHOD OF DETERMINING A TIME TO REPLACE POLISHING PAD

(71) Applicant: EBARA CORPORATION, Tokyo (JP)

(72) Inventors: Yuta SUZUKI, Tokyo (JP); Taro TAKAHASHI, Tokyo (JP); Hirofumi OTAKI, Tokyo (JP); Tsuneo TORIKOSHI, Tokyo (JP); Hiroaki NISHIDA, Tokyo (JP)

(21) Appl. No.: 18/246,366

(22) PCT Filed: Aug. 5, 2021
(86) PCT No.: PCT/JP2021/029120

§ 371 Date: Mar. 23, 2023

(30) Foreign Application Priority Data
Sep. 29, 2020 (JP) 2020-163274

(51) Int. Cl. B24B 37/005; B24B 53/017

(52) U.S. Cl. CPC B24B 37/005; B24B 53/017

(57) ABSTRACT

The present invention relates to a technique of determining a time to replace a polishing pad used in a polishing apparatus for polishing a workpiece, such as wafer, substrate, or panel. A polishing apparatus (1) includes: a polishing table (5) configured to support a polishing pad (2); a polishing head (7) configured to press a workpiece (W) against a polishing surface (2a) of the polishing pad (2); a dresser (40) configured to dress the polishing surface (2a) of the polishing pad (2); a detection sensor (60) configured to detect friction between the dresser (40) and the polishing pad (2), the detection sensor (60) being fixed to the dresser (40); and a wear monitoring device (63) configured to determine a wear index value from a plurality of output values of the detection sensor (60) and generate an alarm signal when the wear index value is smaller than a predetermined lower limit.

### TECHNICAL FIELD

The present invention relates to a technique of determining a time to replace a polishing pad used in a polishing apparatus for polishing a workpiece, such as wafer, substrate, or panel.

### BACKGROUND ART

Chemical mechanical polishing (hereinafter referred to as CMP) is a process of polishing a workpiece (e.g., wafer, substrate, panel, etc.) by rubbing the workpiece against a polishing pad while supplying a polishing liquid containing abrasive grains, such as silica (SiO₂), onto the polishing pad. A polishing apparatus for performing the CMP includes a polishing table that supports the polishing pad having a polishing surface, and a polishing head that presses the workpiece against the polishing pad.

A polishing apparatus polishes the workpiece as follows. While the polishing table and polishing pad are rotated together, a polishing liquid (typically slurry) is supplied onto the polishing surface of the polishing pad. The polishing head rotates the workpiece while pressing the surface of the workpiece against the polishing surface of the polishing pad. The workpiece is held in sliding contact with the polishing pad in the presence of the polishing liquid. The surface of the workpiece is polished by a chemical action of the polishing liquid and a mechanical action of abrasive grains contained in the polishing liquid and the polishing pad.

When the workpiece is polished, the abrasive grains and polishing debris adhere to the polishing surface of the polishing pad, resulting in a decrease in polishing performance. Therefore, in order to regenerate the polishing surface of the polishing pad, dressing of the polishing pad is performed by a dresser. The dresser has hard abrasive grains, such as diamond particles, fixed to its lower surface, and scrapes off the polishing surface of the polishing pad to thereby regenerate the polishing surface of the polishing pad. The dressing of the polishing pad is performed each time a workpiece is polished.

The polishing pad gradually wears as the dressing is repeated. When the polishing pad wears out, an intended polishing performance cannot be achieved. Therefore, it is necessary to periodically replace the polishing pad. In view of this, the polishing pad is replaced with a new one when a usage time of the polishing pad exceeds a predetermined time, or when the number of polished workpieces exceeds a predetermined number.

### CITATION LIST

### Patent Literature

Patent document 1: Japanese laid-open patent publication No. 2012-56029

### SUMMARY OF INVENTION

### Technical Problem

However, the time the polishing pad has been in use and the number of polished workpieces may only indirectly represent the wear of the polishing pad and may not accurately reflect the wear of the polishing pad. As a result, a polishing pad that has not yet reached the end of its service life may be replaced, or a polishing pad that has worn out beyond its use limit may continue to be used. In particular, if an excessively worn polishing pad is used, a target film thickness profile of a workpiece may not be achieved.

Accordingly, the present invention provides an improved technique capable of accurately detecting wear or abnormality of a polishing pad and determining an appropriate processing time or a replacement time of the polishing pad.

### Solution to Problem

In an embodiment, there is provided a polishing apparatus comprising: a polishing table configured to support a polishing pad; a polishing head configured to press a workpiece against a polishing surface of the polishing pad; a dresser configured to dress the polishing surface of the polishing pad; a detection sensor configured to detect friction between the dresser and the polishing pad, the detection sensor being fixed to the dresser; and a wear monitoring device configured to determine a wear index value from a plurality of output values of the detection sensor and generate an alarm signal when the wear index value is smaller than a predetermined lower limit.

In an embodiment, the wear monitoring device is configured to perform a frequency analysis on the plurality of output values arranged along a time axis to determine the wear index value.

In an embodiment, the frequency analysis is a Fourier transform, the wear monitoring device is configured to apply the Fourier transform to the plurality of output values arranged along the time axis to create a power spectrum, and the wear index value is a first peak value of the power spectrum.

In an embodiment, the wear monitoring device is configured to calculate a plurality of relative output values by subtracting the plurality of output values from a plurality of reference values, respectively, and perform the frequency analysis on the plurality of relative output values arranged along a time axis to determine the wear index value.

In an embodiment, the frequency analysis is a Fourier transform, the wear monitoring device is configured to apply the Fourier transform to the plurality of relative output values arranged along the time axis to create a power spectrum, and the wear index value is a first peak value of the power spectrum.

In an embodiment, the plurality of reference values are a plurality of output values of the detection sensor obtained when the dresser dressed the polishing pad for the first time.

In an embodiment, the wear monitoring device is configured to detect abnormality of the polishing pad when a second peak value of the power spectrum is larger than a predetermined upper limit.

In an embodiment, the detection sensor comprises one of an acceleration sensor, an acoustic emission sensor, and a strain sensor.

In an embodiment, the polishing apparatus further comprises: a polishing progress detector configured to generate a polishing index value indicating progress of polishing of the workpiece; and an operation controller configured to monitor the polishing index value, the operation controller being configured to correct the polishing index value based on the wear index value.

In an embodiment, there is provided a method of determining a time to replace a polishing pad used in a polishing apparatus for a workpiece, comprising: detecting friction between a dresser and the polishing pad by a detection sensor fixed to the dresser while dressing a polishing surface of the polishing pad by the dresser; determining a wear index value from a plurality of output values of the detection sensor; and generating an alarm signal when the wear index value is smaller than a predetermined lower limit.

In an embodiment, determining the wear index value comprises performing a frequency analysis on the plurality of output values arranged along a time axis to determine the wear index value.

In an embodiment, the frequency analysis is a Fourier transform, and determining the wear index value comprises applying the Fourier transform to the plurality of output values arranged along the time axis to create a power spectrum, and determining the wear index value which is a first peak value of the power spectrum.

In an embodiment, determining the wear index value comprises calculating a plurality of relative output values by subtracting the plurality of output values from a plurality of reference values, respectively, and performing the frequency analysis on the plurality of relative output values arranged along the time axis to determine the wear index value.

In an embodiment, the frequency analysis is a Fourier transform; and determining the wear index value comprises applying the Fourier transform to the plurality of relative output values arranged along the time axis to create a power spectrum, and determining the wear index value which is a first peak value of the power spectrum.

In an embodiment, the plurality of reference values are a plurality of output values of the detection sensor obtained when the dresser dressed the polishing pad for the first time.

In an embodiment, the method further comprises detecting abnormality of the polishing pad when a second peak value of the power spectrum is larger than a predetermined upper limit.

In an embodiment, the detection sensor is one of an acceleration sensor, an acoustic emission sensor, and a strain sensor.

In an embodiment, the method further comprises correcting a polishing index value indicating progress of polishing of the workpiece based on the wear index value.

### Advantageous Effects of Invention

According to the present invention, the detection sensor fixed to the dresser detects the friction between the dresser and the polishing pad. The output value of the detection sensor gradually changes as the polishing pad wears. In other words, the output value of the detection sensor reflects wear of the polishing pad. Therefore, the wear monitoring device can accurately determine the wear of the polishing pad and a time to replace the polishing pad based on the wear index value determined from the plurality of output values of the detection sensor.

### BRIEF DESCRIPTION OF DRAWINGS

FIG. 1 is a schematic diagram showing an embodiment of a polishing apparatus;

FIG. 2 is a graph showing an example of a temporal change in output value of a detection sensor when a dresser is dressing a polishing surface of a polishing pad;

FIG. 3 is a graph showing an example of a power spectrum created by a wear monitoring device;

FIG. 4 is a graph showing a plurality of reference values arranged along a time axis, a plurality of output values of the detection sensor, and relative output values which are differences between the reference values and the output values of the detection sensor;

FIG. 5 is a diagram showing a power spectrum obtained by applying Fourier transform (or fast Fourier transform) to the relative output values arranged along the time axis shown in FIG. 4;

FIG. 6 is a graph showing another example of a temporal change in the output value of the detection sensor when the dresser is dressing the polishing surface of the polishing pad;

FIG. 7 is a diagram showing a power spectrum obtained by applying Fourier transform (or fast Fourier transform) to a plurality of output values of the detection sensor arranged along the time axis shown in FIG. 6;

FIG. 8 is a graph showing a temporal change in a polishing index value (a film thickness) output from a polishing progress detector when a workpiece is polished using a new polishing pad, and a temporal change in a polishing index value (a film thickness) output from the polishing progress detector when a workpiece is polished using a worn polishing pad; and

FIG. 9 is a diagram showing an example of correlation data.

### DESCRIPTION OF EMBODIMENTS

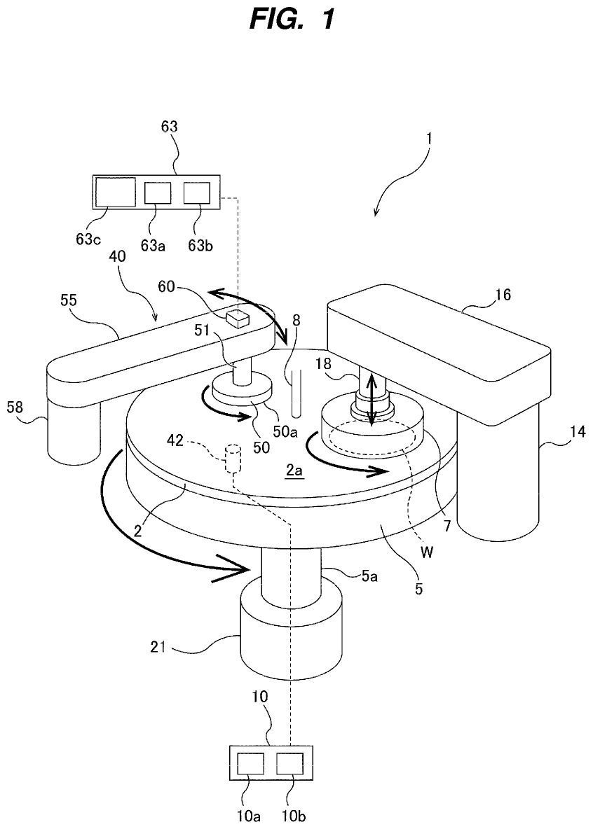

Hereinafter, embodiments of the present invention will be described with reference to the drawings. FIG. 1 is a schematic diagram showing an embodiment of a polishing apparatus. A polishing apparatus 1 is an apparatus for chemically mechanically polishing a workpiece W, such as a wafer, a substrate, or a panel. As shown in FIG. 1, this polishing apparatus 1 includes a polishing table 5 configured to support a polishing pad 2 having a polishing surface 2a, a polishing head 7 configured to press the workpiece W against the polishing surface 2a, a polishing-liquid supply nozzle 8 configured to supply a polishing liquid (e.g., slurry containing abrasive grains) onto the polishing surface 2a, and an operation controller 10 configured to control operations of the polishing apparatus 1. The polishing head 7 is configured to hold the workpiece W on a lower surface thereof. The workpiece W has a film to be polished.

The operation controller 10 is composed of at least one computer. The operation controller 10 includes a memory 10a storing programs therein, and an arithmetic device 10b configured to execute arithmetic operations according to instructions included in the programs. The memory 10a includes a main memory, such as a random-access memory (RAM) and an auxiliary memory, such as a hard disk drive (HDD) or solid-state drive (SSD). Examples of the arithmetic device 10b include a CPU (central processing unit) and a GPU (graphic processing unit). However, the specific configurations of the operation controller 10 are not limited to these examples.

The polishing apparatus 1 further includes a support shaft 14, a polishing-head oscillation arm 16 coupled to an upper end of the support shaft 14, and a polishing-head shaft 18 rotatably supported by a free end of the polishing-head oscillation arm 16. The polishing head 7 is fixed to a lower end of the polishing-head shaft 18. A polishing-head rotating mechanism (not shown) having an electric motor and other elements is arranged in the polishing-head oscillation arm 16. This polishing-head rotating mechanism is coupled to the polishing-head shaft 18 and configured to rotate the polishing-head shaft 18 and the polishing head 7 in a direction indicated by arrow.

The polishing-head shaft 18 is coupled to an unillustrated polishing-head elevating mechanism (including a ball screw mechanism). The polishing-head elevating mechanism is configured to move the polishing-head shaft 18 up and down relative to the polishing-head oscillation arm 16. This vertical movement of the polishing-head shaft 18 allows the polishing head 7 to move vertically relative to the polishing-head oscillation arm 16 and the polishing table 5 as indicated by arrows.

The polishing apparatus 1 further includes a table rotating motor 21 configured to rotate the polishing pad 2 and the polishing table 5 about their axes. The table rotating motor 21 is arranged below the polishing table 5, and the polishing table 5 is coupled to the table rotating motor 21 via a table shaft 5a. The polishing table 5 and the polishing pad 2 are rotated by the table rotating motor 21 about the table shaft 5a in a direction indicated by arrow. The polishing pad 2 is attached to an upper surface of the polishing table 5. An exposed surface of the polishing pad 2 constitutes the polishing surface 2a for polishing the workpiece W, such as a wafer.

Polishing of the workpiece W is performed as follows. The workpiece W, with its surface to be polished facing downward, is held by the polishing head 7. While the polishing head 7 and the polishing table 5 are rotated, the polishing liquid (for example, slurry containing abrasive grains) is supplied onto the polishing surface 2a of the polishing pad 2 from the polishing-liquid supply nozzle 8 provided above the polishing table 5. The polishing pad 2 rotates together with the polishing table 5 about the central axis of the polishing pad 2. The polishing head 7 is moved to a predetermined height by the polishing-head elevating mechanism (not shown). Further, the polishing head 7 presses the workpiece W against the polishing surface 2a of the polishing pad 2 while the polishing head 7 is maintained at the predetermined height. The workpiece W is rotated together with the polishing head 7. With the polishing liquid present on the polishing surface 2a of the polishing pad 2, the workpiece W is brought into sliding contact with the polishing surface 2a. The surface of the workpiece W is polished by a combination of a chemical action of the polishing liquid and a mechanical action of the abrasive grains contained in the polishing liquid and the polishing pad 2.

The polishing apparatus 1 includes a polishing progress detector 42 including a film-thickness sensor for measuring a film thickness of the workpiece W on the polishing surface 2a. The polishing progress detector 42 is configured to generate a polishing index value that directly or indirectly indicates the film thickness of the workpiece W. This polishing index value varies according to the film thickness of the workpiece W, and therefore indicates progress of polishing of the workpiece W. The polishing index value may be a value representing the film thickness itself of the workpiece W, or may be a physical quantity or signal value before being converted into the film thickness.

Examples of the polishing progress detector 42 include an eddy current sensor and an optical film-thickness sensor. The polishing progress detector 42 is installed in the polishing table 5 and rotates together with the polishing table 5. More specifically, the polishing progress detector 42 is configured measure the film thickness at a plurality of measurement points on the workpiece W while traversing the workpiece W on the polishing surface 2a each time the polishing table 5 makes one rotation.

The polishing progress detector 42 is coupled to the operation controller 10. The polishing index value generated by the polishing progress detector 42 is monitored by the operation controller 10. Specifically, film thicknesses at the plurality of measurement points are output from the polishing progress detector 42 as polishing index values, and the polishing index values are sent to the operation controller 10. The operation controller 10 is configured to control the operation of the polishing apparatus 1 based on the polishing index value. For example, the operation controller 10 detects a polishing end point when the polishing index value reaches a predetermined target value.

The polishing progress detector 42 may include, instead of the film-thickness sensor, a torque current detector configured to measure a torque current applied to the table rotating motor 21. When the film forming the surface of the workpiece W is removed by the polishing operation, an underlying layer existing under the film is exposed. Since the film and the underlying layer are composed of different materials, a friction between the workpiece W and the polishing pad 2 changes when the film is removed and the underlying layer is exposed. A change in this friction appears as a change in the torque current applied to the table rotating motor 21. For example, as the friction increases, the torque current required to rotate the polishing table 5 at a preset speed increases. The torque current detector outputs a measured value of the torque current as the polishing index value and sends the measured value of the torque current to the operation controller 10. The operation controller 10 can determine a time at which the film on the workpiece W has been removed based on the change in the torque current.

The polishing apparatus 1 includes a dresser 40 configured to dress the polishing surface 2a of the polishing pad 2. The dresser 40 includes a dressing disk 50 configured to rub against the polishing surface 2a of the polishing pad 2, a dresser shaft 51 coupled to the dressing disk 50, and a dresser oscillation arm 55 rotatably supporting the dresser shaft 51. A lower surface of the dressing disk 50 constitutes a dressing surface 50a, and this dressing surface 50a is composed of abrasive grains (for example, diamond grains).

The dresser shaft 51 is coupled to a not-shown disk pressing mechanism (including, for example, a pneumatic cylinder) disposed within the dresser oscillation arm 55. This disk pressing mechanism is configured to press the dressing surface 50a of the dressing disk 50 against the polishing surface 2a of the polishing pad 2 via the dresser shaft 51. Further, the dresser shaft 51 is coupled to a not-shown disk rotating mechanism (including, for example, an electric motor) disposed in the dresser oscillation arm 55. This disk rotating mechanism is configured to rotate the dressing disk 50 via the dresser shaft 51 in a direction indicated by arrow.

The dressing of the polishing surface 2a of the polishing pad 2 is performed as follows. While the polishing pad 2 is rotated together with the polishing table 5 by the table rotating motor 21, pure water is supplied onto the polishing surface 2a from a pure-water supply nozzle (not shown). While the dressing disk 50 is rotated about the dresser shaft 51 by the disk rotating mechanism (not shown), the dressing surface 50a of the dressing disk 50 is pressed against the polishing surface 2a by the disk pressing mechanism (not shown). The dressing disk 50 is held in sliding contact with the polishing surface 2a in the presence of the pure water on the polishing surface 2a. While the dressing disk 50 is rotating, the dresser oscillation arm 55 swings about the support shaft 58 to oscillate the dressing disk 50 in a radial direction of the polishing surface 2a. In this manner, the polishing pad 2 is scraped off by the dressing disk 50, and the polishing surface 2a is dressed (regenerated). The dressing of the polishing surface 2a of the polishing pad 2 is performed during polishing of the workpiece W or after polishing of the workpiece W.

The polishing apparatus 1 has a detection sensor 60 fixed to the dresser oscillation arm 55. The detection sensor 60 is composed of an acceleration sensor, an acoustic emission sensor (hereinafter referred to as an AE sensor), a strain sensor, or the like. In one embodiment, the detection sensor 60 may be fixed to the dressing disk 50. The detection sensor 60 is a friction detector for detecting friction between the dresser 40 (more specifically, the dressing disk 50) and the polishing pad 2.

For example, when the acceleration sensor is used as the detection sensor 60, vibration of the dressing disk 50 is transmitted to the acceleration sensor when the dressing disk 50 is in sliding contact with the polishing surface 2a of the polishing pad 2. The friction between the dressing disk 50 and the polishing pad 2 is detected as the vibration by the acceleration sensor. It is assumed that the greater the vibration, the greater the friction. When the AE sensor is used as the detection sensor 60, sound wave (elastic wave) is emitted from the dressing disk 50 and the polishing pad 2 while the dressing disk 50 is in sliding contact with the polishing surface 2a of the polishing pad 2. The friction between the dressing disk 50 and the polishing pad 2 is detected as the sound wave (elastic wave) by the AE sensor. The AE sensor converts the sound wave (elastic wave) into an electric signal and outputs the electric signal. When the strain sensor is used as the detection sensor 60, deflection of the dresser oscillation arm 55 is detected by the strain sensor when the dressing disk 50 is in sliding contact with the polishing surface 2a of the polishing pad 2. The friction between the dressing disk 50 and the polishing pad 2 is detected as the deflection of the dresser oscillation arm 55 by the strain sensor. It is estimated that the greater the deflection of the dresser oscillation arm 55, the greater the friction.

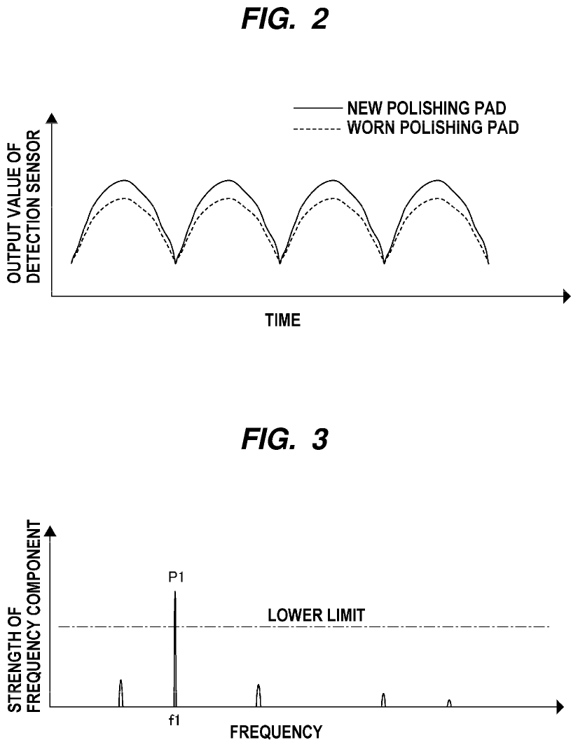

In the embodiments described below, the AE sensor is used as the detection sensor 60. FIG. 2 is a graph showing an example of a temporal change in output value of the detection sensor 60 when the dresser 40 is dressing the polishing surface 2a of the polishing pad 2. Vertical axis in FIG. 2 represents the output value of the detection sensor 60, and horizontal axis in FIG. 2 represents time. During dressing of the polishing pad 2, the dressing disk 50 oscillates (reciprocates) in the radial direction on the polishing surface 2a of the polishing pad 2 as the dresser oscillating arm 55 pivots. Therefore, as shown in FIG. 2, the output value of the detection sensor 60 changes periodically as the dressing disk 50 oscillates. A period of the output value of the detection sensor 60 corresponds to an oscillation period of the dressing disk 50.

Generally, the polishing surface 2a of the polishing pad 2 has a large number of grooves formed therein for retaining the polishing liquid. As the polishing pad 2 wears, depths of the grooves become smaller and the friction between the dressing disk 50 and the polishing pad 2 becomes smaller. As a result, the overall output value of the detection sensor 60 also decreases (see a dotted line in the graph). As the wear of the polishing pad 2 progresses, the polishing pad 2 must be replaced with a new polishing pad. Therefore, in the present embodiment, a time to replace the polishing pad 2 is determined as follows.

As shown in FIG. 1, the polishing apparatus 1 includes a wear monitoring device 63 electrically coupled to the detection sensor 60. The wear monitoring device 63 is configured to acquire a plurality of output values of the detection sensor 60 and determine a wear index value from the plurality of output values of the detection sensor 60. More specifically, the wear monitoring device 63 is configured to perform frequency analysis on the plurality of output values of the detection sensor 60 arranged along a time axis to determine the wear index value. In this embodiment, the frequency analysis is Fourier transform. The wear monitoring device 63 is configured to apply Fourier transform to the plurality of output values of the detection sensor 60 arranged along the time axis to create a power spectrum, and determine the wear index value which is a peak value of the spectrum. The Fourier transform may be a Fast Fourier Transform (FFT). Other examples of the frequency analysis include wavelet analysis, octave analysis, etc.

FIG. 3 is a graph showing an example of the power spectrum created by the wear monitoring device 63. Horizontal axis in FIG. 3 represents frequency of fluctuation of the output value of the detection sensor 60 shown in FIG. 2, and vertical axis in FIG. 3 represents strength of frequency component. As shown in FIG. 3, the power spectrum has a peak value P1 due to the oscillation of the dressing disk 50. A frequency f1 at which this peak value P1 appears corresponds to the oscillation frequency of the dressing disk 50. Therefore, the wear monitoring device 63 can identify the peak value P1 of the power spectrum caused by the oscillation of the dressing disk 50.

The output values of the detection sensor 60 may include noise inherent in the polishing apparatus 1 or noise caused by foreign matter on the polishing pad 2. Due to these noises, as shown in FIG. 3, a plurality of peak values may appear on the power spectrum in addition to the peak value P1. According to this embodiment, the power spectrum can distinguish the peak value P1 caused by the friction between the dressing disk 50 and the polishing pad 2 from other peak values caused by noise. Therefore, the wear monitoring device 63 can monitor the temporal change in the friction between the dressing disk 50 and the polishing pad 2.

In one embodiment, the wear monitoring device 63 may perform noise processing on the output values of the detection sensor 60 to produce corrected output values of the detection sensor 60. For example, the wear monitoring device 63 measures or predicts in advance noise components generated by factors other than the contact between the polishing pad 2 and the workpiece W and the contact between the polishing pad 2 and the dresser 40, and removes the noise components from the output values of the detection sensor 60 to thereby correct the output values of the detection sensor 60. For example, the detection sensor 60 can produce the corrected output values by performing filtering or calculation on output values of the detection sensor 60 when the workpiece W and the dresser 40 are not in contact with the polishing pad 2, output values of the detection sensor 60 when only the polishing head 7 is rotating, output values of the detection sensor 60 when water polishing is performed, output values of the detection sensor 60 when dressing is performed, output values of the detection sensor 60 when water polishing and dressing are performed, output values of the detection sensor 60 when polishing of workpiece W is performed, output values of the detection sensor 60 when polishing of workpiece W and dressing are performed, or a combination thereof. Using the corrected output values of the detection sensor 60 allows for efficient monitoring of the pad surface condition based on the sensor signals at a high SN.

The peak value P1 of the power spectrum gradually decreases as the polishing pad 2 wears. The wear monitoring device 63 is configured to compare the peak value P1 with a predetermined lower limit and generate an alarm signal when the peak value P1 is smaller than the lower limit. This alarm signal causes a display device 63c of the wear monitoring device 63 to display information prompting a user to replace the polishing pad 2.

The output value of the detection sensor 60 gradually changes as the polishing pad 2 wears. In other words, the output value of the detection sensor 60 reflects wear of the polishing pad 2. Therefore, the wear monitoring device 63 can accurately determine the wear of the polishing pad 2 and a time to replace the polishing pad 2 based on the wear index value determined from the plurality of output values of the detection sensor 60.

The wear monitoring device 63 is composed of at least one computer. The wear monitoring device 63 includes a memory 63a storing programs therein, and an arithmetic device 63b configured to performs arithmetic operations according to instructions included in the programs. The memory 63a includes a main memory, such as a random-access memory (RAM) and an auxiliary memory, such as a hard disk drive (HDD) or solid-state drive (SSD). Examples of the arithmetic device 63b include a CPU (central processing unit) and a GPU (graphic processing unit). However, the specific configurations of the wear monitoring device 63 are not limited to these examples. The wear monitoring device 63 may be configured integrally with the operation controller 10. Specifically, the wear monitoring device 63 and the operation controller 10 may be configured by at least one computer including a memory storing programs therein and an arithmetic device configured to executes arithmetic operations according to instructions included in the programs.

In one embodiment, in order to remove noise from the output values of the detection sensor 60, the wear monitoring device 63 may be configured to calculate a plurality of relative output values by subtracting a plurality of output values of the detection sensor 60 from a plurality of reference values, respectively, and perform the frequency analysis on the plurality of relative output values arranged along a time axis to determine a wear index value. In one embodiment, the frequency analysis is a Fourier transform (or fast Fourier transform). The wear monitoring device 63 may be configured to calculate a plurality of relative output values by subtracting a plurality of output values of the detection sensor 60 from a plurality of reference values, respectively, and apply a Fourier transform (or fast Fourier transform) to the plurality of relative output values arranged along a time axis to create a power spectrum.

The plurality of reference values are numerical values acquired during operation of the polishing apparatus 1. For example, the plurality of reference values may be a plurality of output values of the detection sensor 60 obtained when the dresser 40 dressed the polishing pad 2 for the first time. More specifically, after a new polishing pad 2 is attached to the polishing table 5 and before polishing of a workpiece is performed, the dresser 40 performs an initial dressing of the polishing pad 2 while pure water is supplied onto the polishing surface 2a of the polishing pad 2, and a plurality of output values generated by the detection sensor 60 during this initial dressing are designated as the plurality of reference values. The wear monitoring device 63 stores in the memory 63a the plurality of output values acquired from the detection sensor 60 as the plurality of reference values.

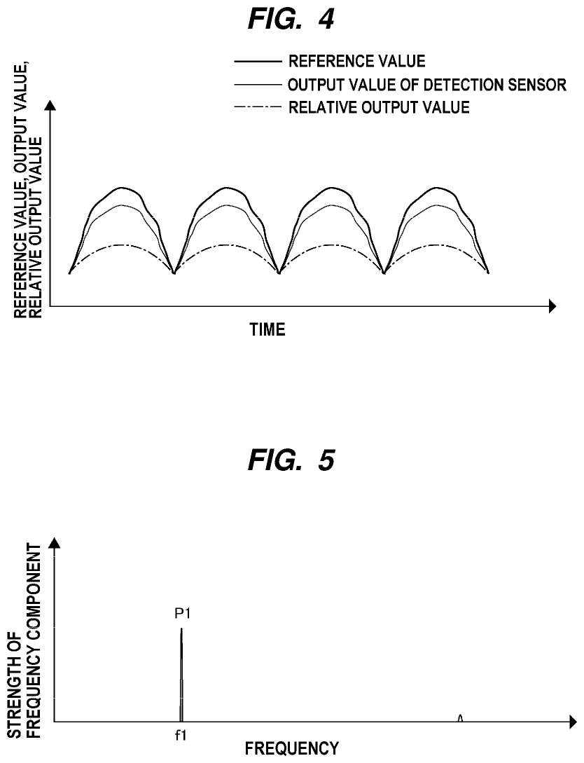

FIG. 4 is a graph showing the plurality of reference values arranged along the time axis, the plurality of output values of the detection sensor 60 arranged along the time axis, and the relative output values which are differences between the reference values and the output values of the detection sensor 60. Vertical axis in FIG. 4 represents the reference value, the output value of the detection sensor 60, and the relative output value, and horizontal axis in FIG. 4 represents time. It can be seen from FIG. 4 that the relative output value changes more smoothly over time than the output value of the detection sensor 60.

FIG. 5 is a diagram showing a power spectrum obtained by applying Fourier transform (or fast Fourier transform) to the relative output values arranged along the time axis shown in FIG. 4. As can be seen from the comparison between the power spectrum shown in FIG. 5 and the power spectrum shown in FIG. 4, the power spectrum shown in FIG. 5 contains less peaks. This means that the relative output values contain little noise.

According to this embodiment, during or after polishing of the workpiece W, the wear monitoring device 63 calculates the plurality of relative output values by subtracting the plurality of output values of the detection sensor 60 from the plurality of reference values. The relative output values, which are indicative of the differences between the reference values and the output values of the detection sensor 60, are values from which noise has been removed. Using such relative output values allows the wear monitoring device 63 to more accurately determine the wear of the polishing pad 2 and a time to replace the polishing pad 2.

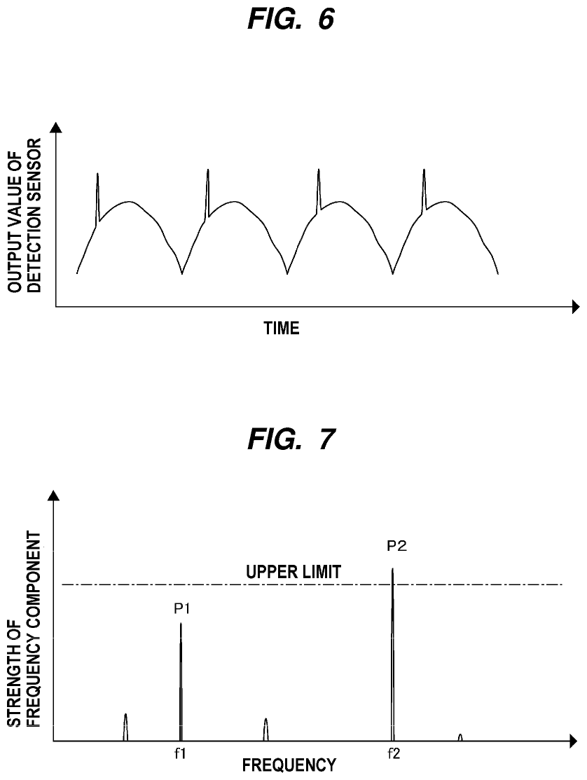

FIG. 6 is a graph showing another example of a temporal changes in the output value of the detection sensor 60 when the dresser 40 is dressing the polishing surface 2a of the polishing pad 2. As shown in the example of FIG. 6, the output value of the detection sensor 60 may temporarily and sharply rise. Such a sudden increase in the output value can be caused by abnormality of the polishing pad 2, such as the presence of foreign matter (polishing debris, abrasive grains, etc.) on the polishing pad 2, partial peeling off of the polishing pad 2, scratches on the polishing surface 2a of the polishing pad 2, or other reasons.

FIG. 7 is a diagram showing a power spectrum obtained by applying Fourier transform (or fast Fourier transform) to the plurality of output values of the detection sensor 60 arranged along the time axis shown in FIG. 6. As shown in FIG. 7, the power spectrum has a peak value P1 at a frequency f1 corresponding to the oscillation of the dressing disk 50, and another peak value P2 caused by the abnormality of the polishing pad 2. This peak value P2 appears at a frequency f2 different from the frequency f1 of the peak value P1. The wear monitoring device 63 is configured to compare the peak value P2 with a predetermined upper limit, detect an abnormality of the polishing pad 2 when the peak value P2 is larger than the predetermined upper limit, and generate an alarm signal that notifies the abnormality of the polishing pad 2. According to the present embodiment, the polishing apparatus 1 can avoid an adverse effect on the polishing of the workpiece W caused by the abnormality of the polishing pad 2 (e.g., foreign matter on the polishing pad 2 or scratches on the polishing pad 2).

The embodiments described with reference to FIGS. 6 and 7 may be combined with the embodiments described with reference to FIGS. 4 and 5.

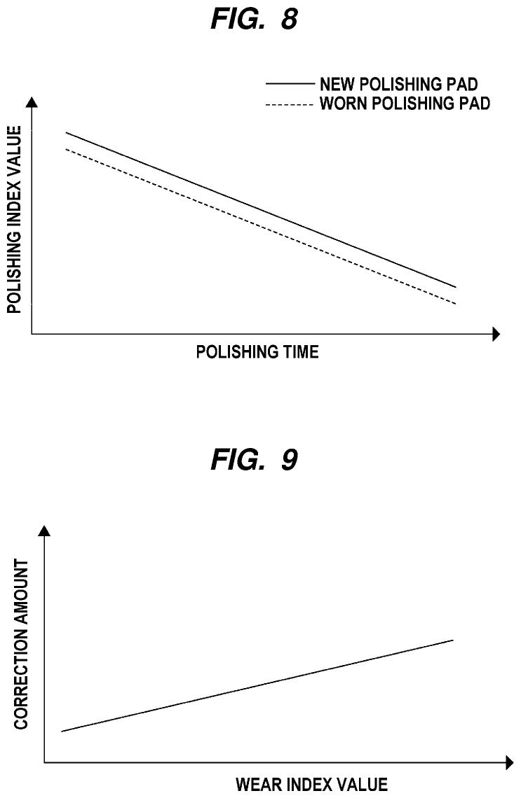

FIG. 8 is a graph showing a change over time in the polishing index value (film thickness) output from the polishing progress detector 42 when a workpiece is polished using a new polishing pad 2, and showing a change over time in the polishing index value (film thickness) output from the polishing progress detector 42 when a workpiece is polished using a worn polishing pad 2. As shown in FIG. 8, the entireties of the polishing index values obtained when the polishing pad 2 has worn are shifted from the polishing index values obtained when the polishing pad 2 is not worn. Specifically, even if the film thickness of the workpiece is the same, the polishing index value output from the polishing progress detector 42 may change depending on the wear of the polishing pad 2. In other words, the change in the polishing index value is correlated with wear of the polishing pad 2.

For example, if the polishing progress detector 42 is an optical film-thickness sensor or an eddy current film-thickness sensor, a distance between the polishing progress detector 42 and a workpiece decreases as the polishing pad 2 wears. As a result, even if the film thickness of the workpiece is the same, the polishing index value (film thickness) output from the polishing progress detector 42 may vary. If a torque current detector is used as the polishing progress detector 42 instead of the film-thickness sensor, the frictional force acting between the workpiece and the polishing pad 2 decreases as the polishing pad 2 wears. As a result, the polishing index value (torque current) output from the polishing progress detector 42 may vary.

Thus, in this embodiment, the operation controller 10 is configured to correct the polishing index value based on the wear index value. The operation controller 10 has correlation data as shown in FIG. 9 stored in advance in the memory 10a. The correlation data shown in FIG. 9 shows an example of the correlation between the wear index value and correction amount of the polishing index value. Although the correlation data is represented by a linear function in the example shown in FIG. 9, the correlation data may be a quadratic function, a cubic function, or the like. Alternatively, the correlation data may be a data table showing the correlation between the wear index value and correction amount of the polishing index value.

The correlation data is created from past wear index values and corresponding polishing index values. Specifically, the correlation data is created from the wear index values obtained when a new polishing pad was used to polish a plurality of workpieces until the polishing pad wore below its use limit, and the polishing index values obtained under the same film thickness conditions.

During polishing of the workpiece W, the operation controller 10 acquires the wear index value sent from the wear monitoring device 63 and uses the correlation data to determine the correction amount corresponding to the wear index value. Then, the operation controller 10 acquires the polishing index value sent from the polishing progress detector 42 during polishing of the workpiece W, and adds the correction amount to the polishing index value (or subtracts the correction amount from the polishing index value) to thereby correct the polishing index value. The operation controller 10 controls the operation of the polishing apparatus 1 based on the corrected polishing index value. For example, the operation controller 10 determines a polishing end point at which the corrected polishing index value reaches a preset target value.

The embodiments described with reference to FIGS. 8 and 9 may be appropriately combined with the embodiments described with reference to FIGS. 1 to 7.

In one embodiment, the output value of the detection sensor 60 may be input into a trained model constructed by deep learning, and a predicted surface condition of the polishing pad 2 may be output from the trained model. Examples of inputs into the trained model include the output value of the detection sensor 60, and the combination of the output value of the detection sensor 60 and parameters, such as table torque and table rotation speed. Examples of outputs from the trained model include an index of a surface condition of the polishing pad 2 or a predicted evaluation value. The wear monitoring device 63 may issue an alert to recommend replacement of the polishing pad 2 when the predicted value approaches a reference value. In addition, the wear monitoring device 63 may output normal use time prediction. The deep learning uses data set including use time of the polishing pad 2, waveform of the output values of the detection sensor 60, and replacement time of the polishing pad 2 which are obtained in the process of actual polishing. This data set can be selected from a data set in which the polishing pad 2 was replaced normally, a data set in which an abnormality occurred during use, and a data set in which normal and abnormal conditions coexisted. The selected data set is used for the learning.

In one embodiment, a camera for generating an image of the polishing surface 2a of the polishing pad 2 may be mounted to the dresser oscillation arm 55. The wear monitoring device 63 can observe the polishing surface 2a using the image of the polishing surface 2a. For example, since the dresser oscillation arm 55 can swing and the polishing table 5 can rotate, the wear monitoring device 63 can observe an arbitrary region of the polishing surface 2a with the camera. A monitoring region of the polishing surface 2a is determined in advance, and the wear monitoring device 63 periodically acquires an image of the polishing surface 2a. The wear monitoring device 63 evaluates a change in a degree of wear of the polishing pad 2 from the image. The wear monitoring device 63 compares the change in the output value of the detection sensor 60 due to the wear of the polishing pad 2 with the image of the polishing surface 2a and can determine an evaluation of the degree of wear of the polishing pad 2 using a plurality of indices. For example, if both evaluation values indicate that it is time to replace, it is possible to avoid an error due to only one judgment. Further, the wear monitoring device 63 can use the sensor signals for identifying a part where an abnormal waveform of the output signals of the detection sensor 60 is generated and can observe that part and determine a solution at an early stage.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a technique of determining a time to replace a polishing pad used in a polishing apparatus for polishing a workpiece, such as wafer, substrate, or panel.

### REFERENCE SIGNS LIST

1 polishing apparatus
2 polishing pad
2a polishing surface
5 polishing table
7 polishing head
8 polishing-liquid supply nozzle
10 operation controller
14 support shaft
16 polishing-head oscillation arm
18 polishing-head shaft
21 table rotating motor
40 dresser
42 polishing progress detector
50 dressing disk
51 dresser shaft
55 dresser oscillation arm
58 support shaft
60 detection sensor
63 wear monitoring device

What is claimed is:

1. A polishing apparatus comprising:
a polishing table configured to support a polishing pad;
a polishing head configured to press a workpiece against a polishing surface of the polishing pad;
a dresser configured to dress the polishing surface of the polishing pad;
a detection sensor configured to detect friction between the dresser and the polishing pad, the detection sensor being fixed to the dresser; and
a wear monitoring device configured to determine a wear index value from a plurality of output values of the detection sensor and generate an alarm signal when the wear index value is smaller than below a predetermined lower limit.

2. The polishing apparatus according to claim 1, wherein the wear monitoring device is configured to perform a frequency analysis on the plurality of output values arranged along a time axis to determine the wear index value.

3. The polishing apparatus according to claim 2, wherein:
the frequency analysis is a Fourier transform;
the wear monitoring device is configured to apply the Fourier transform to the plurality of output values arranged along the time axis to create a power spectrum; and
the wear index value is a first peak value of the power spectrum.

4. The polishing apparatus according to claim 2, wherein the wear monitoring device is configured to calculate a plurality of relative output values by subtracting the plurality of output values from a plurality of reference values, respectively, and perform the frequency analysis on the plurality of relative output values arranged along a time axis to determine the wear index value.

5. The polishing apparatus according to claim 4, wherein:
the frequency analysis is a Fourier transform;
the wear monitoring device is configured to apply the Fourier transform to the plurality of relative output values arranged along the time axis to create a power spectrum; and
the wear index value is a first peak value of the power spectrum.

6. The polishing apparatus according to claim 4, wherein the plurality of reference values are a plurality of output values of the detection sensor obtained when the dresser dressed the polishing pad for the first time.

7. The polishing according to claim 3, wherein the wear monitoring device is configured to detect abnormality of the polishing pad when a second peak value of the power spectrum is larger than a predetermined upper limit.

8. The polishing apparatus according to claim 1, wherein the detection sensor comprises one of an acceleration sensor, an acoustic emission sensor, and a strain sensor.

9. The polishing apparatus according to claim 1, further comprising:
a polishing progress detector configured to generate a polishing index value indicating progress of polishing of the workpiece; and
an operation controller configured to monitor the polishing index value, the operation controller being configured to correct the polishing index value based on the wear index value.

10. A method of determining a time to replace a polishing pad used in a polishing apparatus for a workpiece, comprising:
detecting friction between a dresser and the polishing pad by a detection sensor fixed to the dresser while dressing a polishing surface of the polishing pad by the dresser;
determining a wear index value from a plurality of output values of the detection sensor; and
generating an alarm signal when the wear index value is smaller than a predetermined lower limit.

11. The method according to claim 10, wherein determining the wear index value comprises performing a frequency analysis on the plurality of output values arranged along a time axis to determine the wear index value.

12. The method according to claim 11, wherein:
the frequency analysis is a Fourier transform; and
determining the wear index value comprises applying the Fourier transform to the plurality of output values arranged along the time axis to create a power spectrum, and determining the wear index value which is a first peak value of the power spectrum.

13. The method according to claim 11, wherein determining the wear index value comprises calculating a plurality of relative output values by subtracting the plurality of output values from a plurality of reference values, respectively, and performing the frequency analysis on the plurality of relative output values arranged along the time axis to determine the wear index value.

14. The method according to claim 13, wherein:
the frequency analysis is a Fourier transform; and
determining the wear index value comprises applying the Fourier transform to the plurality of relative output values arranged along the time axis to create a power spectrum, and determining the wear index value which is a first peak value of the power spectrum.

15. The method according to claim 13, wherein the plurality of reference values are a plurality of output values of the detection sensor obtained when the dresser dressed the polishing pad for the first time.

16. The method according to claim 12, further comprising detecting abnormality of the polishing pad when a second peak value of the power spectrum is larger than a predetermined upper limit.

17. The method according to claim 10, wherein the detection sensor is one of an acceleration sensor, an acoustic emission sensor, and a strain sensor.

18. The method according to claim 10, further comprising correcting a polishing index value indicating progress of polishing of the workpiece based on the wear index value.
